(19) United States
(12) Patent Application Publication
(10) Pub. No.: US 2026/0229451 A1
(43) Pub. Date: Aug. 6, 2026

(54) QUANTIFYING FILM ACCUMULATION ON AN INSULATING SURFACE IN SEMICONDUCTOR PROCESSING EQUIPMENT

(71) Applicant: Axcelis Technologies, Inc., Beverly, MA (US)

(72) Inventors: Rajen Sud, Burlington, MA (US); Yusef Nouri, Beverly, MA (US)

(21) Appl. No.: 19/457,142

(22) Filed: Jan. 22, 2026

Related U.S. Application Data
(60) Provisional application No. 63/752,375, filed on Jan. 31, 2025.

(51) Int. Cl. H01J 37/244; H01J 37/30; H01J 37/317; H10P 72/00

(52) U.S. Cl. CPC H01J 37/244; C23C 14/545; H01J 37/3007; H01J 37/3171; H10P 72/0604; H01J 2237/24564; H01J 2237/24578; H01J 2237/24592; H01J 2237/31705

(57) ABSTRACT

Ions are generated using an ion source and directed toward a workpiece on a chuck. Resistance and/or reactance between at least two pick-up measurement wires and a stimulating electrode in a sensor is measured. The sensor is on a surface of a chamber that the ions are within. The surface is fabricated of a material that is an insulator. A thickness of a film accumulation on the surface is determined using the resistance and/or the reactance between the at least two pick-up measurement wires and the stimulating electrode

### CROSS-REFERENCE TO RELATED APPLICATIONS

This application claims priority to the provisional patent application filed Jan. 31, 2025 and assigned U.S. App. No. 63/752,375, the disclosure of which is hereby incorporated by reference.

### FIELD OF THE DISCLOSURE

This disclosure relates to film measurement in semiconductor processing equipment and, more particularly, film measurement in ion implanters.

### BACKGROUND OF THE DISCLOSURE

In the manufacture of semiconductor devices, ion implantation is used to dope semiconductors with impurities. Ion implantation systems are often used to implant a workpiece, such as a semiconductor wafer, with ions from an ion beam to produce n-type or p-type material doping or to form passivation layers during fabrication of an integrated circuit. Such beam treatment can selectively implant the wafers with impurities of a specified dopant material, at a predetermined energy level, and in controlled concentration to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material workpiece, whereas a “p-type” extrinsic material workpiece often results from ions generated with source materials such as boron, gallium, or indium.

A typical ion implanter includes an ion source, an ion extraction device, a mass analysis device, a beam transport device, and a process chamber. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, workpieces are transferred in and out of the process chamber via a workpiece handling system, which may include one or more robotic arms, for placing a workpiece to be treated in front of the ion beam and removing treated workpieces from the ion implanter.

As an ion beam at certain masses and energies strikes surfaces within the implanter, such as the workpiece or hardware components, the ion beam can cause atoms to be sputtered from and larger particles to be liberated from the surfaces. These atoms and larger particles then deposit themselves on other surfaces and can form a poorly-adhering thin film or loose particles. The particles can be transported by the ion beam from surfaces in the ion implanter back to the workpiece, which can damage devices on the workpiece. An ion beam at smaller energies and/or with smaller ions also can cause film accumulation on a surface directly instead of via sputtering. To reduce the generation of particles produced by films delaminating from surfaces, preventative maintenance is performed on various components in the implanter.

### BRIEF SUMMARY OF THE DISCLOSURE

A system is provided in a first embodiment. The system includes an ion source configured to generate ions; a chuck configured to hold a workpiece; a chamber that the ions are within; a sensor with at least two pick-up measurement wires and a stimulating electrode disposed on a surface of the chamber; a power source in electronic communication with the stimulating electrode; and a processor in electronic communication with the sensor. The ions may be in an ion beam. The sensor measures resistance and/or reactance between the at least two pick-up measurement wires and the stimulating electrode. The surface is fabricated of a material that is an insulator. The at least two pick-up measurement wires and the stimulating electrode may be fabricated of a metal that is not copper. The at least two pick-up measurement wires and the stimulating electrode also may be fabricated of copper. The processor is configured to determine a film accumulation on the surface using the resistance and/or the reactance between the at least two pick-up measurement wires and the stimulating electrode. The processor may be further configured to determine film lift-off from the surface. The processor may be further configured to send instructions to perform preventative maintenance on the system based on the film accumulation. The surface with the sensor may be a terminal bushing, a shield, a process chamber, or a window.

A method is provided in a second embodiment. A method includes generating ions using an ion source. The ions are directed toward a workpiece on a chuck. The ions may be in an ion beam. The workpiece may be a semiconductor wafer. Resistance and/or reactance between at least two pick-up measurement wires and a stimulating electrode in a sensor is measured. The sensor is disposed on a surface of a chamber that the ions are within. The at least two pick-up measurement wires and the stimulating electrode may be fabricated of a metal that is not copper. The at least two pick-up measurement wires and the stimulating electrode also may be fabricated of copper. The surface is fabricated of a material that is an insulator. Using a processor, a thickness of a film accumulation on the surface is determined using the resistance and/or the reactance between the at least two pick-up measurement wires and the stimulating electrode. The method can include determining film lift-off from the surface using the processor. The method can include sending instructions using the processor to perform preventative maintenance on the system based on the film accumulation. The surface with the sensor may be a terminal bushing, a shield, a process chamber, or a window.

### DESCRIPTION OF THE DRAWINGS

For a fuller understanding of the nature and objects of the disclosure, reference should be made to the following detailed description taken in conjunction with the accompanying drawings, in which:

FIG. 1 is a diagram of an embodiment of a sensor in accordance with the present disclosure;

FIG. 2 is a diagram of another embodiment of a sensor in accordance with the present disclosure;

FIG. 3 is a diagram of another embodiment of a sensor in accordance with the present disclosure;

FIG. 4 is a diagram of another embodiment of a sensor in accordance with the present disclosure;

FIG. 5 illustrates exemplary distances between pick-up measurement wires and stimulating electrodes;

FIG. 6 and FIG. 7 are charts showing a number of resistors and an equivalent resistance for a number of nodes;

FIGS. 8-13 illustrate changes in measurements as a film accumulates on a surface in a semiconductor processing system; and

FIG. 14 is a diagram showing an embodiment of a vacuum system in accordance with the present disclosure;

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments disclosed herein determine film accumulation in an ion implanter or other plasma processing system. By determining film accumulation, preventative maintenance can be scheduled as-needed instead of based on hours of operation or a calendar cycle. This will reduce system downtime and operating costs.

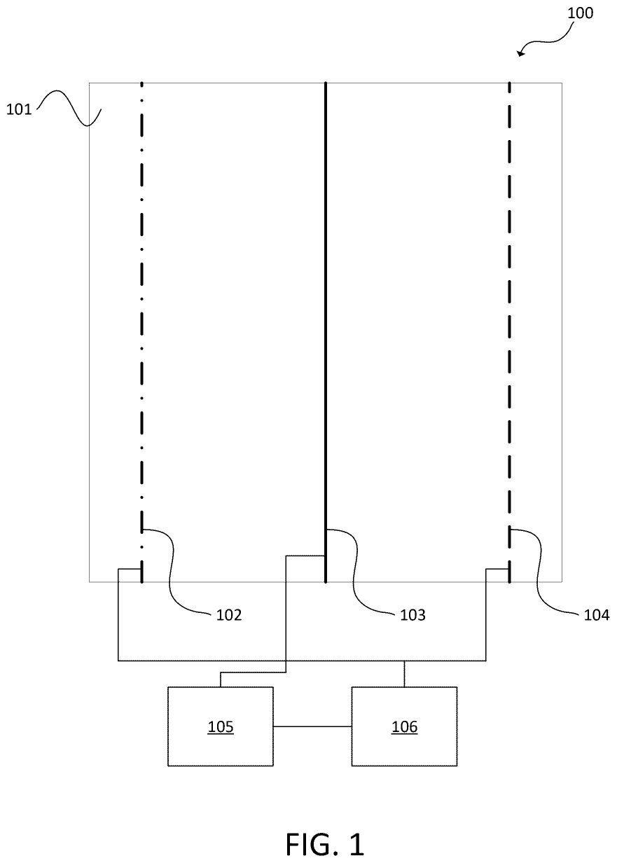

FIGS. 1-4 illustrate embodiments of sensors that can be used in semiconductor processing equipment. The sensor 100 in FIG. 1 is disposed on a surface 101 fabricated of an insulating material. For example, the surface 101 can be polycarbonate (e.g., LEXAN), glass, plexiglass, ceramics, epoxy resin, polyether ether ketone (PEEK), sapphire, diamond, or other insulating materials. The surface 101 may be inside an ion implanter or other semiconductor processing equipment. This surface 101 may be prone to film accumulation because it is exposed to particles in the semiconductor processing equipment. The sensor 100 can be exposed on the surface 101, but the sensor 100 is generally not disposed directly in the path of ions or an ion beam to prevent damage to the sensor 100. However, particles in semiconductor processing equipment can travel with an ion beam toward the surface 101 or can be deposited on the surface 101.

The sensor 100 includes pick-up measurement wire 102 (which is solid, but shown with dashed-dot line for ease of understanding), which can be used to determine if a substantial film is present on the surface 101. The sensor 100 also includes a stimulating electrode 103 and a second pick-up measurement wire 104 (which is solid, but shown with dashed line for ease of understanding). The wires that make up the pick-up measurement wire 102, stimulating electrode 103, and the second pick-up measurement wire 104 may have the same specifications or different specifications, such as diameter. The stimulating electrode 103 can operate using alternating current (AC) or direct current (DC) power. The second pick-up measurement wire 104 may have a higher sensitivity than the pick-up measurement wire 102, so the second pick-up measurement wire 104 can be used to determine if a new film is depositing on the surface 101. The pick-up measurement wire 102, stimulating electrode 103, and second pick-up measurement wire 104 may be disposed on the surface 101, recessed in a body of the electrode extending to the surface 101, or inside a body of the surface 101 a distance from the surface 101.

The stimulating electrode 103 is connected to a power source 105. In an embodiment, the power source 105 is only connected with the stimulating electrode 103 in the sensor 100. The power source 105 provides the stimulus to the stimulating electrode 103. When stimulating with AC power, pick-up measurement wire 102 can measure the phase between the voltage and current over a span of frequencies and based on the change in phase over the frequency span. Thus, the reactive value of the film can be determined, either through capacitive or inductive measurements. Voltage leads the current in an inductive load, while current leads the voltage in a capacitive load. The magnitude of the phase difference determines the reactive value.

For example, by running an AC signal of various frequencies on the stimulating electrode 103, the pick-up measurement wire 102 or second pick-up measurement wire 104 can be monitored to determine a reactance value. With the second pick-up wire 104 disconnected, such as using a switch, relay, or solid-state relay, then the properties of the film between stimulating electrode 103 and pick-up measurement wire 102 can be measured. By then switching so that the pick-up measurement wire 102 is disconnected instead of the second pick-up wire 104, the properties of the film between stimulating electrode 103 and the second pick-up measurement wire 104 can be measured instead.

Incidental coatings on the walls or windows produced during the implantation process are not uniform in thickness, as evidenced by the thin film interference producing a spectrum of colors resembling a rainbow as a function of film thickness. By using a geometry shown in FIGS. 1-4 and placing the detecting surface aligned perpendicular to the changing colors region of the thin film, then the property of two film areas can be determined in this transitional region using a single stimulating electrode 103.

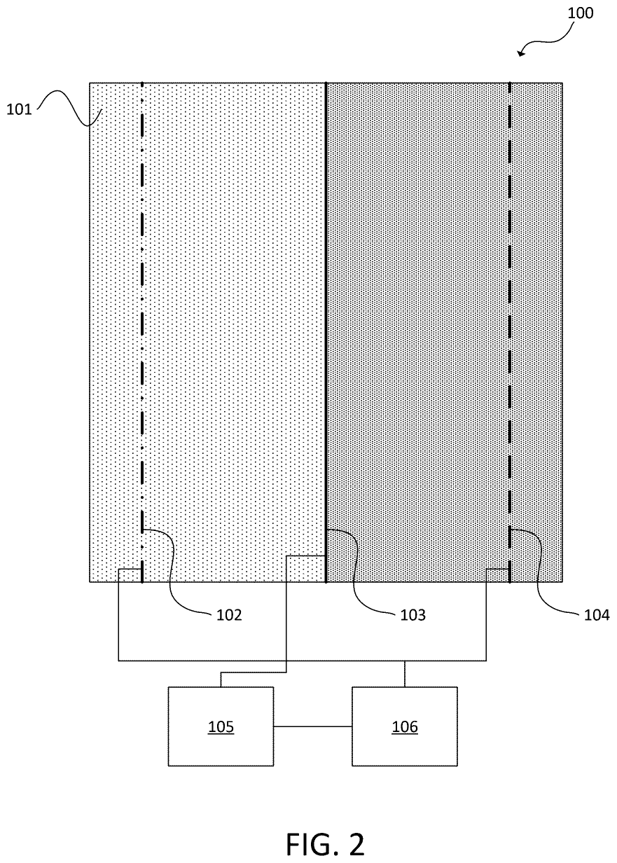

The strength of various thin-films adhesions to surfaces has a dependency on the surface texture. Rougher surfaces adhere films better than smooth surfaces. If the surface area between the pick-up measurement wire 102 and stimulating electrode 103 is textured differently from the surface area between the second pick-up measurement wire 104 and stimulating electrode 103, then two different adherences to film accumulation can be monitored and warned about. An embodiment is shown in FIG. 2. The surface area between the pick-up measurement wire 102 and stimulating electrode 103 is a different material than the surface area between second pick-up measurement wire 104 and stimulating electrode 103, as shown with the different shading. For example, the surface area between the pick-up measurement wire 102 and stimulating electrode 103 may be plexiglass and the surface area between second pick-up measurement wire 104 and stimulating electrode 103 may be ceramic. If measurements indicate that a film is thicker on one of the materials or flaking on one of the materials, then this information can be used to focus cleaning on surfaces with that material during preventative maintenance. Other materials can be used, and these are merely examples. Besides using different materials, the texture can be affected by modifying the surface finish. Thus, different surface finishes can be used in the surface area between the pick-up measurement wire 102 and stimulating electrode 103 and the surface area between second pick-up measurement wire 104 and stimulating electrode 103. Different surface finishes can be used together with different materials or in lieu of the different materials.

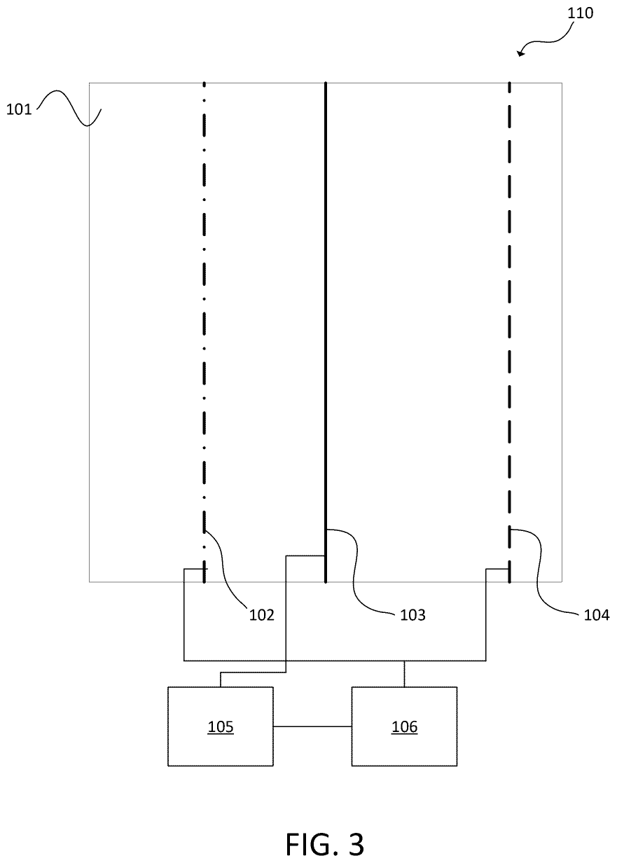

If the distance between pick-up measurement wire 102 and stimulating electrode 103 is different than the distance between second pick-up measurement wire 104 and stimulating electrode 103 using the sensor 110 shown in FIG. 3, then two different ranges of measurements can be achieved similar to what is being shown with the two different pick-up measurement wire patterns in FIG. 4. When a new component with the surface 101 is installed in an implanter without any films accumulated, the resistance will be at its maximum achievable value determined by the surface 101. While in this new, high resistance condition, the stimulating electrode 103 can stimulate while measuring using the pick-up measurement wire 102 due to the shorter distance separating them in FIG. 3. As films accumulate and reduce the insulation value of surface 101, measuring can be performed using the second pick-up measurement wire 104, which would increase the distance of separation and the resistance that is measured. Using different separating distances between the stimulating (e.g., the stimulating electrode 103) and the pick-up measurement wire 102 and second pick-up measurement wire 104 may enable operation over an increased range of surface resistances that a component may experience over an installed lifetime in an implanter or other semiconductor processing equipment.

FIG. 4 shows a sensor 115. The sensor 115 can be disposed on a surface 101 fabricated of an insulating material. Like sensor 100, the sensor 115 includes a pick-up measurement wire 102, a stimulating electrode 103, and a second pick-up measurement wire 104. Components of the sensor 115 can be connected to a power source 105 and can be in electronic communication with a processor 106 like the sensor 100. The processor 106 can take measurements from the pick-up measurement wire 102 and second pick-up measurement wire 104 to determine a film accumulation on the surface 101 using the resistance and/or the reactance between the pick-up measurement wire 102, stimulating electrode 103, and second pick-up measurement wire 104.

The pick-up measurement wire 102 and second pick-up measurement wire 104 are interwoven between the stimulating electrode 103. Since the range of reactance and resistance due to film accumulation can vary over the life of the component, then multiple parallel wires/electrodes at various distances apart from each other, or multiple patterns with various areas in between, can enable multiple “ranges” to cover the operating space of the sensor 115. For example, when first installed with no film accumulation, resistances may be substantial (e.g., >100 kOhm) and may benefit from a shorter distance (or increased area) between the stimulating electrode 103 and one of the pick-up measurement wire 102 or second pick-up measurement wire 104. As the film accumulates and resistance drops, the pick-up measurement wire 102 can be used, which can increase the distance between wires/electrodes and the resulting resistance. If a portion of the film in the area delaminates and “flakes” off, a step response in resistance and reactance may be detectable to trigger a warning to perform preventative maintenance. If multiple wires/electrodes at various distances are implemented, then only one pick-up would be measured at a time while the others are left open or subject to high impedance.

In the embodiments of FIGS. 1-4, the AC frequency can range from approximately 10 Hz to approximately 100 kHz (e.g., 100 Hz, 1 kHz, or 10 kHz). In another example, a DC signal is run to the stimulating electrode 103, then the remaining wire(s) or electrode can be monitored to determine a resistance value. Stimulating with DC current enables a resistance measurement, R, whereas stimulating with AC current enables a reactance measurement, X. Impedance, Z, is the combination of the real component, R, and the imaginary component, X using the formula Z=R+jX. The stimulation voltage may be selected to avoid an arc current. An arc current may ablate a section of the thin film or produce a conductive carbon trace, which will modify the properties of the film that is being measured.

A distance between the stimulating electrode 103 and the pick-up measurement wire 102 and second pick-up measurement wire 104 may be proportional to the output voltage applied by the power supply 105. For example, a stimulating electrode 103 outputting 10 V with a separation distance to the measurement wire of 1 inch would be equivalent to a stimulating electrode outputting 20 V with a separation distance to the measurement wire of 2 inches in an ideal circumstance. With two different pick-up measurement geometries and/or distances, operating space can be increased without increasing output voltage of the power source 105. For example, to measure gigaohm resistances, relatively high voltages may need to be applied, such as from approximately 3,000 V to 5,000 V. When the resistance drops by a factor of 1,000×, the stimulating voltage required would also nearly drop 1,000×. So, by using two different distances between stimulating and measuring that approach an approximately 1,000× difference, a single common stimulating voltage can span the operating space.

In FIGS. 1-4, a processor 106 is in electronic communication with the pick-up measurement wire 102, second pick-up measurement wire 104, and power source 105. The processor 106 can take measurements from the pick-up measurement wire 102 and second pick-up measurement wire 104 to determine a film accumulation on the surface 101 using the resistance and/or the reactance between the pick-up measurement wire 102 and stimulating electrode 103 or the stimulating electrode 103 and second pick-up measurement wire 104. A negative reactance is capacitive while a positive reactance is inductive. A reactance measurement can, thus, be capacitive or inductive at a given time. A reactance measurement cannot be both capacitive and inductive simultaneously. It can only be real (resistance) if the imaginary reactance component is 0 ohms (i.e., neither capacitive nor inductive).

The processor 106 can be in electronic communication with the power source 105 to configure the output properties such as the voltage level, DC or AC, and the frequency of the AC if selected. A processor 106 is also in electronic communication with analog-to-digital converter(s) (ADC) that are connected to the pick-up measurement wire 102 and second pick-up measurement wire 104. The processor 106 can coordinate cycling through the power source 105 output configurations (e.g., test conditions) and determines when to sample the ADC measurements from the pick-up measurement wire 102 and the second pick-up measurement wire 104. The processor 106 may compare the history of voltage and current measurements stored in memory by test condition over time to quantify film accumulation on the surface 101 using the changes in resistance and reactance (i.e., capacitance or inductance) between the pick-up measurement wire 102, stimulating electrode 103, and second pick-up measurement wire 104. The analog-to-digital converter (ADC) connects to the pick-up measurement wire 102 and second pick-up measurement wire 104 and can take an analog measurement of both, the voltage and current, and convert the two values to digital signals the processor 106 can interpret and store in memory. This digital communication between the ADC and processor can take on many various standard communication formats such as serial communication (like SPI or QSPI or I2C or others) or parallel communication.

The processor 106 typically is a programmable processor, which is programmed in software and/or firmware to carry out the functions that are described herein, along with suitable digital and/or analog interfaces for connection to the other elements of sensor 100. Alternatively or additionally, the processor 106 can include hard-wired and/or programmable hardware logic circuits, which carry out at least some of the functions of the processor 106. Although the processor 106 is shown in FIGS. 1-4, for the sake of simplicity, as a single, monolithic functional block, in practice the processor 106 may comprise multiple, interconnected control units, with suitable interfaces for receiving and outputting the signals that are illustrated in the figures and are described in the text. Program code or instructions for the processor 106 to implement various methods and functions disclosed herein may be stored in readable storage media, such as a memory.

The pick-up measurement wire 102, stimulating electrode 103, and second pick-up measurement wire 104 are fabricated of a metal in the embodiments of FIGS. 1-4. The metal can be, for example, gold, silver, aluminum, or tin. In another example, copper can be used for specific applications. The metal is not copper for certain applications because copper can negatively impact devices being fabricated on a semiconductor wafer or other workpiece. The wires/electrodes can be manufactured using various techniques, such as plating and etching the conductors on or in the surface 101. For example, this can be a similar manufacturing process as that used in PCB or flex-cable manufacturing.

The rate of incidental film accumulation is generally slow, such that a component may only get replaced after 300 to 1,500 hours of production implantation. Over that span of time, the rate of change in the resistance and reactance measurements will generally change slowly and linearly. Over time, by reaching a critical mass and/or going through a sufficient thermal cycling event, a thin-film coating may begin delaminating into a flake, either partially or fully separating from the bulk film on the insulating surface 101 in a relatively quick event. This can lead to a discontinuity (step response) in the resistance and reactance measurements recorded.

In addition to the processor 106 trending the thin film growth, the processor 106 can monitor for signs of thin film delamination events from discontinuities in the resistance and/or reactance measurements. The processor 106 also can trigger a warning or interlock so corrective maintenance can be executed earlier than the otherwise scheduled preventative maintenance interval. This can improve device yields by reducing particle migration.

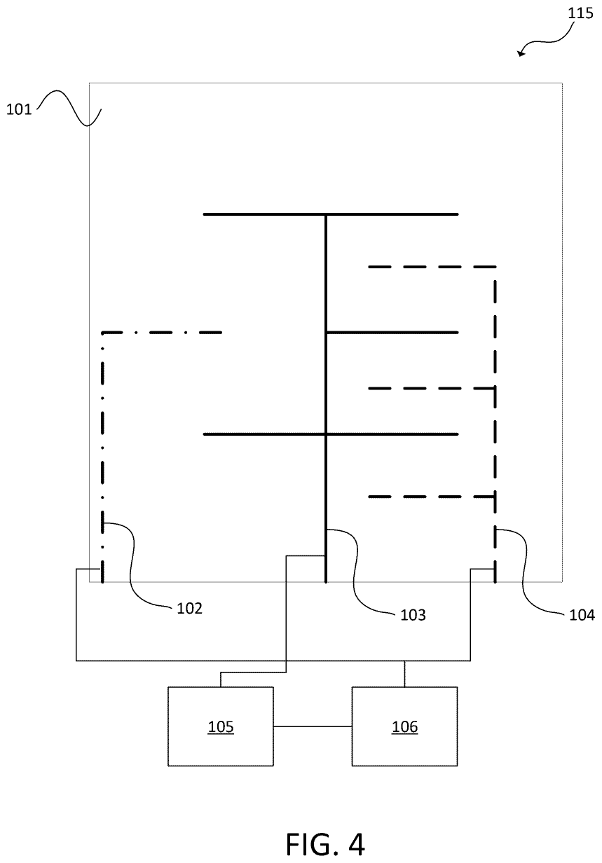

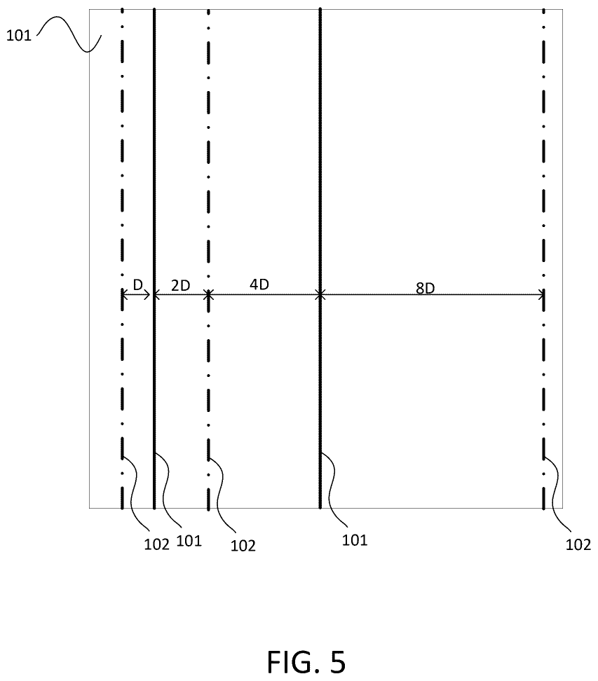

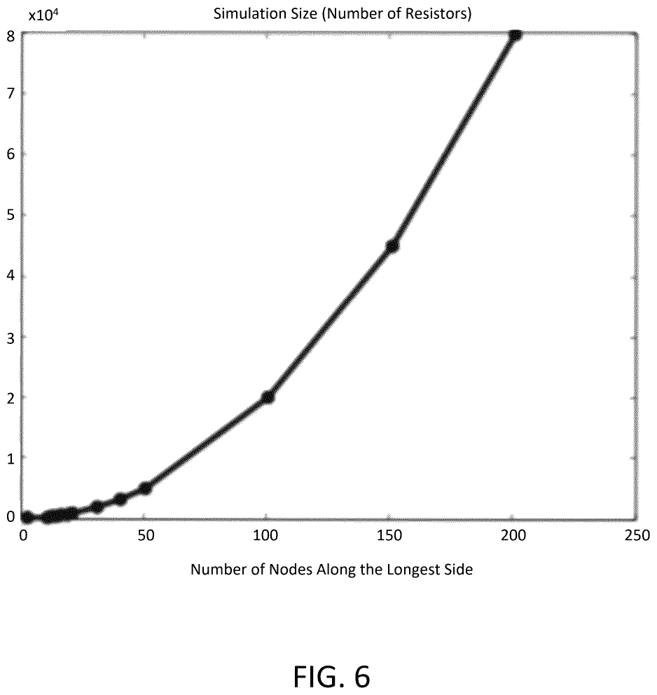

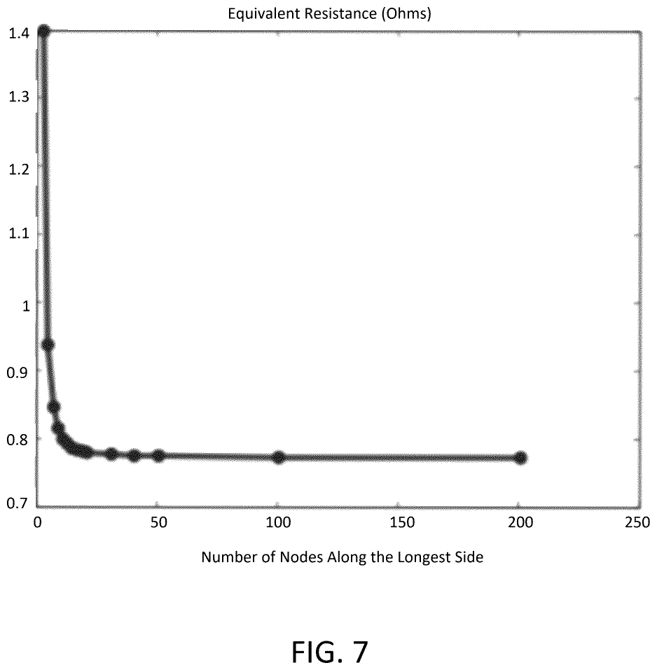

FIG. 5 illustrates exemplary distances between pick-up measurement wires and stimulating electrodes. A pick-up measurement wire 102 is used in FIG. 5 for ease of illustration, but this also can be a second pick-up wire 104 or an additional pick-up measurement wire. Turning to FIG. 6 and FIG. 7, as more of a film coating is applied to a “perfect” insulator, the resistance measurement will flatten out approaching some minimum value in FIG. 7 whereby it becomes difficult to quantify further film accumulation. Where this flattening occurs depends on the distance D separating the stimulating and pick-up measurement electrode shown in FIG. 5. By increasing the distance D, the sensitivity is moved to a region with slope that once again will be sensitive to further film accumulation. In FIG. 5, measurements may start with the region with distance D until the equivalent resistance value starts saturating near a minimum resistance value. Then the measurements may move to the distance 2D using the next pick-up measurement wire 102, such as by changing the measurement connected to an ADC. After the distance 2D region saturates, the 4D region may be used for measurements, such as by changing the stimulating electrode 101 activated by a power source. The 8D distance region can be used when the 4D region saturates. This can continue to span a desired range of voltages of film resistance measurement for a given power source voltage.

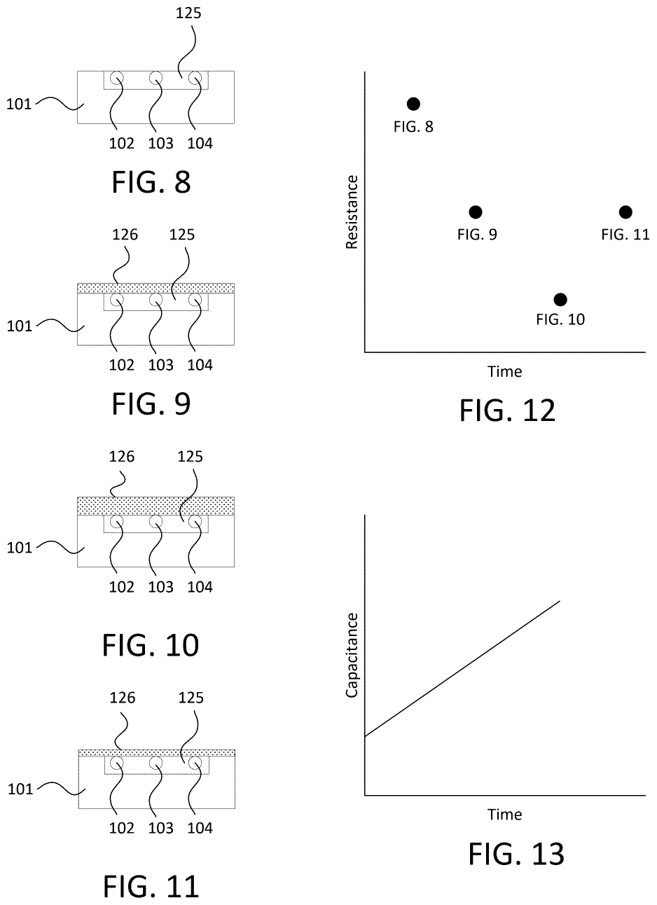

FIGS. 8-13 illustrate changes in measurements as a film 126 accumulates on a surface 101 in a semiconductor processing system. FIGS. 8-11 include a sensor 125, which can be, for example, the sensor 100, sensor 115, sensor 120, or another embodiment of a sensor disclosed herein. The sensor 125 is positioned on or in the surface 101. While illustrated in FIGS. 8-11 as disposed in the surface 101, the sensor 125 also can be raised partly or fully above the surface 101. The surface 101 and the region in the sensor 125 may be an insulator, which may be the same material or different materials. The sensor 125 can include other wires or electrodes as illustrated in the embodiments, such as those illustrated in FIGS. 1-4 or in other embodiments described herein. Corresponding exemplary resistances and capacitances are illustrated in FIGS. 12 and 13 as the film 126 increases in thickness. These resistances and capacitances are shown in FIGS. 12 and 13 without scales for comparison. For example, in FIG. 12 the resistance data point for FIG. 8 is a baseline. The resistance decreases in data points for FIG. 9 and FIG. 10. The resistance increases when some or all of the film 126 flakes off or begins to flake off, as shown with the data point for FIG. 11. In FIG. 12, the capacitance continues to increase over time (as illustrated in FIGS. 8-11) if the layers in the film 126 are made of different materials (e.g., aluminum and nitrogen compounds). These resistances and capacitances in FIGS. 12 and 13 are exemplary and are not intended to be limiting.

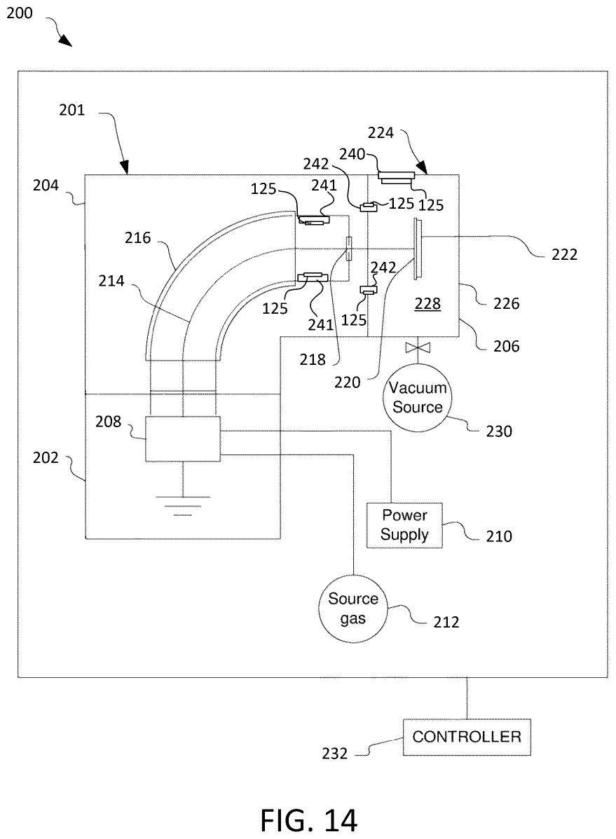

In FIGS. 8-11, the sensor 125 can be used to measure resistance, capacitance, and/or inductance between the electrodes in the sensor 125. For example, the surface 101 can be in an ion implanter (such as that shown in FIG. 14). As explained with FIG. 14, an ion implanter can generate ions with an ion source and direct the ions toward a workpiece on a chuck, such as in the form of an ion beam that implants a semiconductor wafer. The ions can be present in a chamber that includes the sensor 125. As shown in FIGS. 8-11, the ions can form a film 126 on the surface 101 or can cause other materials to form a film 126 on the surface. The film 126 can include, for example, photoresist components, implant species, or sputtered material like aluminum or silicon.

There is no film on the surface 101 in FIG. 8. A resulting resistance and capacitance are shown in FIGS. 12 and 13. A film 126 grows on the surface 101 in FIG. 9. As shown in FIG. 12, the resistance decreases as the film 126 increases in thickness. A thicker film 126 is shown in FIG. 10 in comparison to FIG. 9. As shown in FIG. 12, the resistance continues to decrease as the film 126 increases in thickness.

Using the measurements from the sensor 120, a thickness of a film 126 accumulation on the surface 101 can be determined using a processor. This can be based on the resistance, the capacitance, and/or the inductance between the electrodes in the sensor 125. For example, a decreasing resistance can be used to determine a thickness of the film 126. The electrical properties of the film 126 can depend on the materials in the film 126, so these determinations can be at least partly based on the ions or other species that are present in the system, the materials of the workpiece, and/or the materials of the hardware components in the system.

The reactance and resistance measurements can be correlated to the film accumulation rates to detect flaking events when a film begins to delaminate from the surface, which is a precursor to the particle generation that can impact device yields. Lift-off of the film 126 from the surface 101 can be determined using the processor. For example, if the resistance increases suddenly, then this can indicate that part of the film 126 has flaked or fallen off the surface 101. For example, compare the resistance values in FIG. 12 between data points for FIG. 10 with a thicker film 126 and FIG. 11 with a thinner film 126. This difference in resistance values going between data points for FIG. 10 and FIG. 11 (or going between data points for FIG. 11 and FIG. 8 with no film) can indicate a flaking event. Thus, a flaking event can include losing some or all of the film 126 from the surface 101. A flaking event also can include a discontinuity in the film 126, such as a blister or a pocket.

Depending on the measurements of the film 126 (e.g., total thickness or change in thickness), the processor can send instructions to perform preventative maintenance due to the accumulation or flaking of the film 126. The preventative maintenance can be performed on an as-needed basis, which reduces total downtime for the system. A more targeted preventative maintenance schedule can improve throughput for the system. For example, the instructions for preventative maintenance can be performed when the film reaches a particular thickness, if a film has accumulated in certain parts of the system, if the possibility of film lift-off exceeds a risk threshold, or if film lift-off is detected. A warning or interlock communication can be sent.

FIG. 14 illustrates an exemplified vacuum system 200 that may implement various apparatus, systems, and methods of the present disclosure. The vacuum system 200 includes an ion implantation system 201, however various other types of vacuum systems are also contemplated, such as plasma processing systems or other semiconductor processing systems. The ion implantation system 201, for example, comprises a terminal 202, a beamline assembly 204, and an end station 206.

Generally speaking, an ion source 208 in the terminal 202 is coupled to a power supply 210, whereby a gas from a gas source 212 (also called a dopant gas) supplied thereto and/or material from a target is ionized into a plurality of ions to form an ion beam 214 (such as ion beam 107). The ion beam 214 is directed through a beam-steering apparatus 216 and out an aperture 218 toward the end station 206. In the end station 206, the ion beam 214 bombards a workpiece 220 (e.g., a silicon wafer, a display panel, etc.), which is selectively clamped or mounted to a chuck 222 (e.g., an electrostatic chuck). The workpiece 220 can include semiconductor devices under fabrication. Once embedded into the lattice of the workpiece 220, the implanted ions change the physical and/or chemical properties of the workpiece 220. Because of this, ion implantation is used in semiconductor device fabrication and in metal finishing, as well as various applications in materials science research.

The ion beam 214 of the present disclosure can take any form, such as a pencil or spot beam, a ribbon beam, a scanned beam, or any other form in which ions are directed toward end station 206, and all such forms are contemplated as falling within the scope of the disclosure.

The end station 206 includes a process chamber 224, such as a vacuum chamber 226, wherein a process environment 228 is associated with the process chamber. The process environment 228 within the process chamber 224, for example, comprises a vacuum produced by a vacuum source 230 (e.g., a vacuum pump) coupled to the process chamber 224 and configured to substantially evacuate the process chamber 224. A controller 232, which can include a processor, is provided for overall control of the vacuum system 200. The controller 232 can be or can include the processor 106. A separate processor 106 in electronic communication with the controller 232 also may be used.

The ion source 208 (also called an ion source chamber), for example, can be constructed using refractory metals (W, Mo, Ta, etc.) and graphite in order to provide suitable high temperature performance, whereby such materials are generally accepted by semiconductor manufacturers. The gas from the gas source 212 is used within the ion source 208. The gas may or may not be conductive in nature.

As shown in FIG. 14, one or more sensors 125 can be positioned around the ion implantation system 201. In an instance, the sensor 125 can be positioned on a window 240 in the process chamber 224. In another instance, the sensor 125 can be positioned as part of a terminal bushing 242, which can be between chambers or components in a chamber (e.g., the beamline assembly 204 and end station 206). In yet another instance, the sensor 125 can be positioned on a shield 241. The window 240, shield 241, and terminal bushing 242 can be in other positions around the ion implantation system 201 than that illustrated in FIG. 14. For example, the shield 241 can be in the ion source 208. The ion implantation system 201 can include a single sensor 125 or can include multiple sensors 125. The sensors 125 can each have a surface area from approximately 1 cm² to 900 cm².

The embodiments of the present disclosure also may be implemented in various semiconductor processing equipment such as chemical vapor deposition (CVD), physical vapor deposition (PVD), plasma-enhanced chemical vapor deposition (PECVD), metal organic chemical vapor deposition (MOCVD), etching equipment, and various other semiconductor processing equipment, and all such implementations are contemplated as falling within the scope of the present disclosure.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
an ion source configured to generate ions;
a chuck configured to hold a workpiece;
a chamber that the ions are within;
a sensor with at least two pick-up measurement wires and a stimulating electrode disposed on a surface of the chamber, wherein the sensor measures resistance and/or reactance between the at least two pick-up measurement wires and the stimulating electrode, and wherein the surface is fabricated of a material that is an insulator;
a power source in electronic communication with the stimulating electrode; and
a processor in electronic communication with the sensor, wherein the processor is configured to determine a film accumulation on the surface using the resistance and/or the reactance between the at least two pick-up measurement wires and the stimulating electrode.

2. The system of claim 1, wherein the ions are in an ion beam.

3. The system of claim 1, wherein the at least two pick-up measurement wires and the stimulating electrode are fabricated of a metal that is not copper.

4. The system of claim 1, wherein the at least two pick-up measurement wires and the stimulating electrode are fabricated of copper.

5. The system of claim 1, wherein the processor is further configured to determine film lift-off from the surface.

6. The system of claim 1, wherein the processor is further configured to send instructions to perform preventative maintenance on the system based on the film accumulation.

7. The system of claim 1, wherein the surface with the sensor is a terminal bushing.

8. The system of claim 1, wherein the surface with the sensor is a shield.

9. The system of claim 1, wherein the chamber is a process chamber.

10. The system of claim 1, wherein the surface is a window.

11. A method comprising:
generating ions using an ion source;
directing the ions toward a workpiece on a chuck;
measuring resistance and/or reactance between at least two pick-up measurement wires and a stimulating electrode in a sensor, wherein the sensor is disposed on a surface of a chamber that the ions are within, and wherein the surface is fabricated of a material that is an insulator; and
determining, using a processor, a thickness of a film accumulation on the surface using the resistance and/or the reactance between the at least two pick-up measurement wires and the stimulating electrode.

12. The method of claim 11, wherein the ions are in an ion beam.

13. The method of claim 11, wherein the at least two pick-up measurement wires and the stimulating electrode are fabricated of a metal that is not copper.

14. The method of claim 11, further comprising determining film lift-off from the surface using the processor.

15. The method of claim 11, further comprising sending instructions to perform preventative maintenance on the system based on the film accumulation using the processor.

16. The method of claim 11, wherein the surface with the sensor is a terminal bushing.

17. The method of claim 11, wherein the surface with the sensor is a shield.

18. The method of claim 11, wherein the chamber is a process chamber.

19. The method of claim 11, wherein the surface is a window.

20. The method of claim 11, wherein the workpiece is a semiconductor wafer.
